(19) United States
(12) Patent Application Publication
(10) Pub. No.: US 2021/0134926 A1
(43) Pub. Date: May 6, 2021

(54) DISPLAY DEVICE

(71) Applicant: LG Display Co., Ltd., Seoul (KR)

(72) Inventor: MoonBong SONG, Paju-si (KR)

(21) Appl. No.: 16/984,907

(22) Filed: Aug. 4, 2020

(30) Foreign Application Priority Data
Nov. 4, 2019 (KR) 10-2019-0139268

(51) Int. Cl. H01L 27/32; H01L 27/15; H01L 25/16

(52) U.S. Cl. CPC H01L 27/3276; H01L 25/167; H01L 27/156

(57) ABSTRACT

Present disclosure relates to display devices. In according to embodiments of the present disclosure, in a structure in which a sub-pixel in accordance with embodiments of the present disclosures a light emitting portion including a light emitting element, and the like, and a transmissive portion not including the light emitting element, and the like, is disposed, it is possible to prevent a slit with a constant width between sub-pixel lines from being formed by enabling a ratio of transmissive area between sub-pixel lines to be formed irregularly through a location adjustment of the transmissive portion in the sub-pixel. Accordingly, while an area of a transmissive portion included in each sub-pixel is maintained constantly, a diffraction phenomenon caused by a transmissive area formed between sub-pixel lines can be prevented, and the sharpness of images represented by transparent display devices can be improved.

### CROSS-REFERENCE TO RELATED APPLICATION

This application claims the priority benefit of Korean Patent Application No. 10-2019-0139268, filed on Nov. 4, 2019 in the Korean Intellectual Property Office, the disclosure of which is incorporated herein by reference in its entirety BACKGROUND

### TECHNICAL FIELD

The present disclosure relates to display devices.

### DESCRIPTION OF THE RELATED ART

As the information society has developed, there are increasing needs for display devices displaying images Recently, various types of display devices, such as a liquid crystal display device, an organic light emitting display device, a quantum dot display device, and the like, have been developed and utilized.

The organic light emitting display device of these display devices uses an organic light emitting diode which is a self-emissive element and therefore has several advantages in viewing angle, response speed, luminous efficiency, and the like.

Further, unlike the liquid crystal display device, since the organic light emitting display device does not include a backlight unit, thus, the organic light emitting display device may be implemented as various types of display devices. For example, the organic light emitting display device may be implemented as a transparent display device.

The transparent display device may be implemented, for example, by allocating a transmissive area in an area other than an area of a sub-pixel in which a light emitting element such as a light emitting diode or the like is disposed.

### BRIEF SUMMARY

The inventors have realized that although it is possible to increase the utilization of the area of the display device according to the aforementioned conventional art, some phenomena, such as interference or diffraction of light passing through the transmission area included in the subpixel, and the like, may occur. Also, the inventors have found out that such phenomena in turn may lead the image being displayed through the transparent display device to be affected, or background images to be unclear. Based on the inventors work in fully locating and appreciating these issues, the inventors have proposed solutions as described herein.

In accordance with embodiments of the present disclosure, methods are provided for reducing a diffraction phenomenon of light caused by a transmissive area in a display device including the transmissive area that is transparent in a sub-pixel.

In accordance with embodiments of the present disclosure, methods are provided for reducing a diffraction phenomenon of light caused by a transmissive area included in sub-pixels, while maintaining a ratio of the transmissive area included in the sub-pixels.

In accordance with one or more embodiments of the present disclosure, a display device is provided that includes a plurality of first signal lines that is arranged in a first direction, a plurality of second signal lines that is arranged in a second direction different from the first direction, and a plurality of sub-pixels each including a light emitting portion to which signals are provided from at least one of the first signal lines and at least one of the second signal lines and at least one transmissive portion located on at least one side of the light emitting portion.

In three sub-pixels arranged to be adjacent to one another in the first direction among a plurality of sub-pixels included in a display device, when a ratio between areas of transmissive portions located on both sides of a light emitting portion of a first sub-pixel is X1:Y1; a ratio between areas of transmissive portions located on both sides of a light emitting portion of a second sub-pixel is X2:Y2; and a ratio between areas of transmissive portions located on both sides of a light emitting portion of a third sub-pixel is X3:Y3, X1+Y1, X2+Y2 and X3+Y3 may be equal, and Y1+X2 and Y2+X3 may be different.

In accordance with other embodiments of the present disclosure, a display device is provided that includes a plurality of sub-pixels arranged in an active area, a plurality of light emitting portions included in the respective plurality of sub-pixels, a plurality of transmissive portions included in the respective plurality of sub-pixels and located on at least one side of at least one of the respective light emitting portions, in which widths of the transmissive portions arranged to be adjacent in a first direction are different, and widths of the transmissive portions arranged to be adjacent in a second direction different from the first direction are different are constant.

In accordance with further embodiments of the present disclosure, a display device is provided that includes a plurality of first signal lines arranged in a first direction, a plurality of second signal lines arranged in a second direction different from the first direction, and a plurality of sub-pixels each including a light emitting portion to which signals are provided from at least one of the first signal lines and at least one of the second signal lines, and at least one transmissive portion located on at least one side of the light emitting portion, in which at a boundary of two sub-pixels arranged to be adjacent in the first direction among the plurality of sub-pixels, two light emitting portions included in the two sub-pixels are disposed to contact each other, or two transmissive portions included in the two sub-pixels are disposed to contact each other.

In accordance with embodiments of the present disclosure, by enabling one or more area(s) of one or more transmissive portion(s) located between light emitting portions included in a plurality of sub-pixels to be aperiodic, it is possible to reduce the diffraction phenomenon of light caused by the transmissive portions and thus improve the sharpness of images.

In accordance with embodiments of the present disclosure, while an area of a transmissive portion located in a sub-pixel is maintained constantly, by enabling one or more area(s) of one or more transmissive portion(s) located between light emitting portions included in adjacent sub-pixels to be aperiodic, it is possible to improve the sharpness of images without reducing the transmittance of the transparent display device.

### BRIEF DESCRIPTION OF THE SEVERAL VIEWS OF THE DRAWINGS

FIG. 1 schematically illustrates a configuration of a display device according to embodiments of the present disclosure.

FIG. 2 schematically illustrates a transparent display device as one example of the display device according to embodiments of the present disclosure.

FIGS. 3A to 3C illustrate a structure in which at least one light emitting portion and at least one transmissive portion are located in a subpixel disposed in the display device according to embodiments of the present disclosure.

FIG. 4 illustrates a structure in which at least one light emitting portion and at least one transmissive portion are located in a plurality of sub-pixel lines according to one embodiment of the present disclosure.

FIG. 5 illustrates a structure in which at least one light emitting portion and at least one transmissive portion are located in a plurality of sub-pixel lines according to another embodiment of the present disclosure.

FIG. 6 illustrates examples of candidate structures in which at least one light emitting portion and at least one transmissive portion are located in each sub-pixel line according to embodiments of the present disclosure.

FIGS. 7 and 8 illustrate structures in which at least one light emitting portion and at least one transmissive portion are located in sub-pixel lines arranged to be adjacent according to embodiments of the present disclosure.

FIG. 9 illustrates a structure in which at least one light emitting portion and at least one transmissive portion are located in a plurality of sub-pixel lines according to further another embodiment of the present disclosure.

FIG. 10 illustrates a structure in which at least one signal line is arranged in a plurality of sub-pixel lines including at least one light emitting portion and at least one transmissive portion according to embodiments of the present disclosure.

FIG. 11 illustrates a structure in which at least one light emitting portion and at least one transmissive portion are located in a plurality of sub-pixel lines taking account of at least one signal line located outside of an active area according to embodiments of the present disclosure.

FIG. 12 illustrates a structure in which at least one light emitting portion and at least one transmissive portion are located in a boundary of the active area according to embodiments of the present disclosure.

### DETAILED DESCRIPTION

In the following description of examples or embodiments of the present disclosure, reference will be made to the accompanying drawings in which it is shown by way of illustration specific examples or embodiments that can be implemented, and in which the same reference numerals and signs can be used to designate the same or like components even when they are shown in different accompanying drawings from one another. Further, in the following description of examples or embodiments of the present disclosure, detailed descriptions of well-known functions and components incorporated herein will be omitted when it is determined that the description may make the subject matter in some embodiments of the present disclosure rather unclear. The terms such as “including,” “having,” “containing,” “constituting” “make up of,” and “formed of” used herein are generally intended to allow other components to be added unless the terms are used with the term “only.” As used herein, singular forms are intended to include plural forms unless the context clearly indicates otherwise.

Terms, such as “first,” “second,” “A,” “B,” “(A),” or “(B)” may be used herein to describe elements of the present disclosure. Each of these terms is not used to define essence, order, sequence, or number of elements, etc., but is used merely to distinguish the corresponding element from other elements.

When it is mentioned that a first element “is connected or coupled to,” “contacts or overlaps,” etc., a second element, it should be interpreted that, not only can the first element “be directly connected or coupled to” or “directly contact or overlap” the second element, but a third element can also be “interposed” between the first and second elements, or the first and second elements can “be connected or coupled to,” “contact or overlap,” etc., each other via a fourth element. Here, the second element may be included in at least one of two or more elements that “are connected or coupled to,” “contact or overlap,” etc., each other.

When time relative terms, such as “after,” “subsequent to,” “next,” “before,” and the like, are used to describe processes or operations of elements or configurations, or flows or steps in operating, processing, manufacturing methods, these terms may be used to describe non-consecutive or non-sequential processes or operations unless the term “directly” or “immediately” is used together.

In addition, when any dimensions, relative sizes etc., are mentioned, it should be considered that numerical values for an elements or features, or corresponding information (e.g., level, range, etc.) include a tolerance or error range that may be caused by various factors (e.g., process factors, internal or external impact, noise, etc.) even when a relevant description is not specified. Further, the term “may” fully encompasses all the meanings of the term “can.”

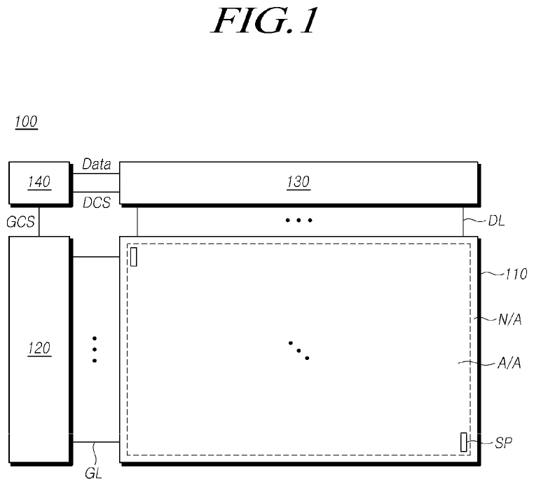

FIG. 1 is a block diagram illustrating a display device 100 according to embodiments of the present disclosure.

Referring to FIG. 1, the display device 100 may include a display panel 110 including an active area AA in which images are displayed and a non-active area NA located adjacent of the active area AA, a gate driving circuit 120, a data driving circuit 130, and a controller 140, which are for driving the display panel 110, and the like.

A plurality of data lines DL and a plurality of gate lines GL are arranged in the display panel 110, and a plurality of subpixels SP is arranged in areas adjacent to the overlapping locations of the data lines DL and the gate lines GL. Each sub-pixel may include several circuit components, and one pixel may include two or more sub-pixels.

The gate driving circuit 120 is controlled by the controller 140, and controls driving timings of the plurality of subpixels by sequentially outputting scan signals to the plurality of gate lines GL arranged in the display panel 110.

Further, the gate driving circuit 120 can provide light-emitting timing signals for controlling light emitting timings of the sub-pixels SP. The circuit providing the scan signal and the circuit providing the light-emitting signal may be implemented integrally or separately.

The gate driving circuit 120 may include one or more gate driver integrated circuits GDIC. The gate driving circuit 120 may be located on one side or both sides of the display panel 110, such as, a left or right side, a top or bottom side, the left and right sides, or the top and bottom sides, according to the various driving schemes. Further, the gate driving circuit 120 may be implemented in a Gate In Panel (GIP) type in which the gate driving circuit 120 is located in at least one bezel area (e.g., area within the non-active area NA) of the display panel 110.

The data driving circuit 130 receives image data from the controller 140 and then converts the received image data into analog data voltages. The data driving circuit 130 outputs a data voltage to each data line DL according to a timing at which a scan signal through the gate line GL is applied, and enables each subpixel SP to emit light according to the image data.

The data driving circuit 130 may include one or more source driver integrated circuits SDIC. Further, the data driving circuit 130 may be located on one side or both sides of the display panel 110, such as, a left or right side, a top or bottom side, the left and right sides, or the top and bottom sides, according to various driving schemes.

The controller 140 provides several control signals to the gate driving circuit 120 and the data driving circuit 130, and controls operations of the gate driving circuit 120 and the data driving circuit 130.

The controller 140 enables the gate driving circuit 120 to output a scan signal according to timing processed in each frame, converts image data input from external devices or image providing sources to a data signal form used in the data driving circuit 130, and then outputs image data resulted from the converting to the data driving circuit 130.

The controller 140 receives, along with the image data, several types of timing signals including a vertical synchronous signal VSYNC, a horizontal synchronous signal HSYNC, an input data enable signal DE, a clock signal CLK, etc., from other devices, networks, or systems (e.g., a host system).

The controller 140 may generate several types of control signals using the received timing signals from an outside source such as the host system, and output the generated signals to the gate driving circuit 120 and the data driving circuit 130.

In one embodiment, to control the gate driving circuit 120, the controller 140 outputs several types of gate control signals GCS including a gate start pulse GSP, a gate shift clock GSC, a gate output enable signal GOE, and the like.

Here, the gate start pulse GSP is used for controlling a start timing for operating one or more gate driver integrated circuits GDIC included in the gate driving circuit 120. The gate shift clock GSC is a clock signal commonly inputted to one or more gate driver integrated circuits GDIC, and is used for controlling a shift timing of a scan signal. The gate output enable signal GOE is used for indicating timing information of one or more gate driver integrated circuits GDIC.

Further, to control the data driving circuit 130, the controller 140 outputs several types of data control signals DCS including a source start pulse SSP, a source sampling clock SSC, a source output enable signal SOE, and the like.

Here, the source start pulse SSP is used for controlling a data sampling start timing of one or more source driver integrated circuits SDIC included in the data driving circuit 130. The source sampling clock SSC is a clock signal for controlling a sampling timing of data in each source driving integrated circuit SDIC. The source output enable signal SOE is used for controlling an output timing of the data driving circuit 130.

The display device 100 may supply several types of voltage or current to the display panel 110, the gate driving circuit 120, and the data driving circuit 130 etc., or may further include a power management integrated circuit for controlling several types of voltage or current to be supplied.

Several circuit components may be located in each sub-pixel SP. For example, a liquid crystal or a light emitting element ED may be located in the sub-pixel SP depending on types of display device 100. Such a light emitting element ED may be, for example, an organic light emitting diode OLED or an inorganic light emitting diode LED, and in some instances, a micro light emitting diode (LED) with a size of several tens of km.

Further, the sub-pixel SP may include a transparent area in which circuit components are not located, in addition to an area in which circuit components or light emitting elements ED are arranged. That is, when a transparent display device is used as the display device 100, the sub-pixel SP may include a transparent area.

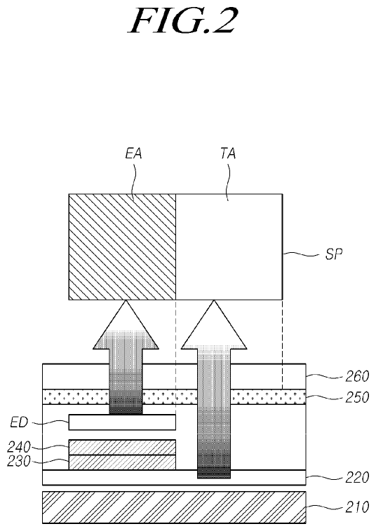

FIG. 2 schematically illustrates a transparent display device as one example of the display device 100 according to embodiments of the present disclosure.

Referring to FIG. 2, a lower transparent substrate 220 may be located on a transparent plate 210, and a thin film transistor layer 230 on which a plurality of thin film transistors for driving a light emitting element ED is located may be located on the lower transparent substrate 220.

A first electrode layer 240 may be disposed on the thin film transistor layer 230, and the light emitting element ED may be disposed on the first electrode layer 240. The first electrode layer 240 may be an anode electrode of the light emitting element ED. A second electrode layer 250 may be disposed on the thin film transistor layer ED, and an upper transparent substrate 260 may be disposed on the second electrode layer 250. The second electrode layer 250 may be a cathode electrode of the light emitting element ED.

Here, a sub-pixel SP may include a light emitting portion EA in which the light emitting element ED, one or more circuit component(s) for driving the light emitting element ED, and the like are located, a transmissive portion TA in which the light emitting element ED and the circuit component are not located.

That is, the light emitting element ED and the circuit component may be vertically overlapped in a plan view. Thus, as a sub-pixel SP includes the transmissive portion TA in which the light emitting element ED etc., is not disposed, the display device 100 may be implemented as a transparent display device.

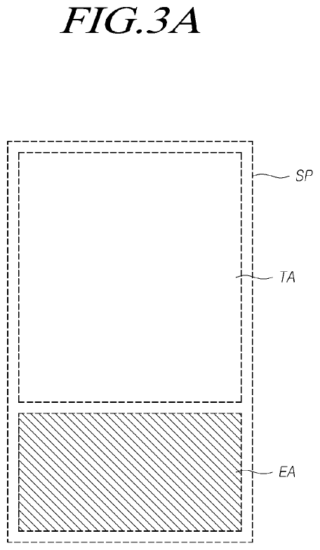

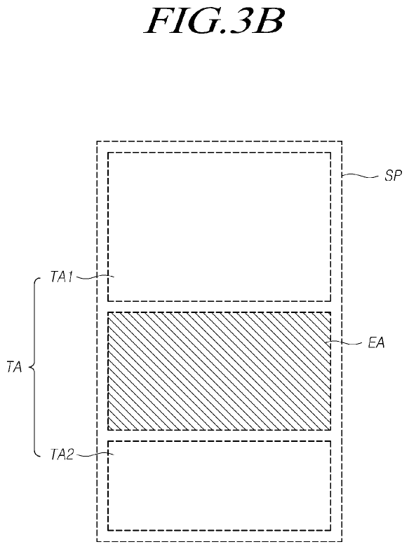

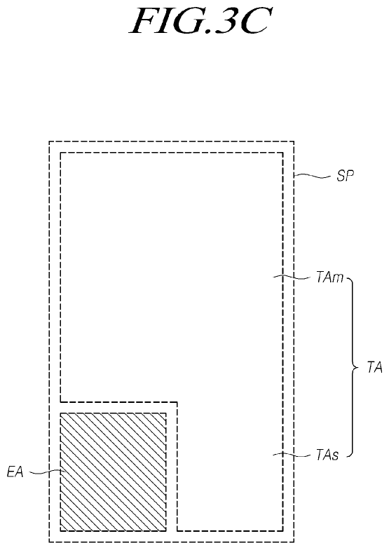

FIGS. 3A to 3C illustrate a structure in which at least one light emitting portion EA and at least one transmissive portion TA are located in a subpixel SP disposed in the display device 100 according to embodiments of the present disclosure.

Referring to FIG. 3A, the sub-pixel SP may include the light emitting portion EA in which a light emitting element ED etc., is located, and the transmissive portion TA in which the light emitting element ED etc., is not located. Further, in the sub-pixel SP, the light emitting portion EA may be located to contact a boundary of the sub-pixel SP.

In some instances, the light emitting portion EA may be located to be spaced apart from at least a part of the boundary of the sub-pixel SP.

Referring to FIG. 3B, the light emitting portion EA in which the light emitting element etc., is located may be located in the central area of the sub-pixel SP.

Transmissive portions TA may be located on both neighboring sides of the light emitting portion EA. In one example, a first transmissive portion TA1 may be located on one side of the light emitting portion EA, and a second transmissive portion TA2 may be located on the other side of the light emitting portion EA. The locations and arrangements of the light emitting portion EA and one or more transmissive portions TA may differ according to various embodiments.

An area of the light emitting portion EA is needed to be greater to increase luminance efficiency of the sub-pixel SP, and an area of the transmissive portion TA may be needed to be greater to increase transmittance. Accordingly, respective areas and locations of the light emitting portion EA and the transmissive portion TA for enabling the luminance efficiency and the transmittance to be increased may be variously determined.

Further, the transmissive portion TA located in the sub-pixel SP may be disposed in a shape other than a rectangular shape.

Referring to FIG. 3C, the light emitting portion EA may be located in at least a part of the sub-pixel SP.

The transmissive portion TA may include a main transmissive portion TAm located on one side of the light emitting portion EA, and an auxiliary transmissive portion TAs located on the other side of the light emitting portion EA and connected to the main transmissive portion TAm.

That is, the transmissive portion TA located in the sub-pixel SP may be disposed in various shapes for allowing transmittance of the sub-pixel SP to be increased. In some instances, the transmissive portion TA may be disposed to be separated from the light emitting portion EA in the sub-pixel SP (FIG. 3B), or be disposed in a structure in which the transmissive portion TA surrounds at least a part of an edge of the light emitting portion EA (FIG. 3C).

Thus, in accordance with the embodiments of the present disclosure, a transparent display device may be effectively provided by locating a transmissive portion TA in various shapes in a sub-pixel SP.

Here, when a transmissive portion TA is located in a substantial equal shape in each sub-pixel SP, transmissive portions TA of a plurality of sub-pixels SP may form one or more slit(s), and thus, in turn, a diffraction phenomenon may occur by light passing through the transmissive portions TA. Further, when the transmissive portions TA are disposed irregularly to reduce the diffraction phenomenon, some difficulties may exist in forming a subpixel SP structure.

In according to embodiments of the present disclosure, a method is provided of maintaining an area of a transmissive portion TA and easily forming a structure of a sub-pixel SP, while avoiding the periodic arrangements of transmissive portions TA within the sub-pixels SP.

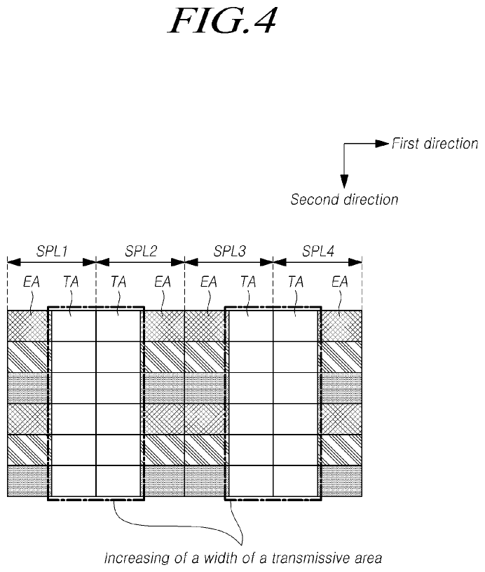

In one embodiment, FIG. 4 illustrates a structure in which one or more light emitting portions EA and one or more transmissive portions TA are located in a plurality of sub-pixel lines SPL.

Referring to FIG. 4, a plurality of sub-pixels arranged in an equal row or column among a plurality of sub-pixels SP may form a sub-pixel line SPL.

Although FIG. 4 illustrates that a plurality of sub-pixels arranged in an equal column forms a sub-pixel line SPL, embodiments of the present disclosure may be equally applied to a structure in which a plurality of sub-pixels arranged in an equal row forms a sub-pixel line SPL.

One or more light emitting portions EA and one or more transmissive portions TA included in one or more sub-pixels SP arranged in each sub-pixel line SPL may be arranged to be aligned with one another. In one example, one or more light emitting portions EA and one or more transmissive portions TA located in one or more sub-pixels of a first sub-pixel line SPL1 may be arranged to be aligned with one another in a second direction. Further, one or more light emitting portions EA and one or more transmissive portions TA located in one or more other sub-pixel lines SPL may be also arranged to be aligned with one another in the second direction.

At a boundary of adjacent sub-pixel lines SPL in a first direction, light emitting portions EA or transmissive portions TA included in respective sub-pixels of the adjacent sub-pixel lines may be arranged to contact one another. In one or more embodiments, the first direction is transverse to the second direction.

In one example, at a boundary of the first subject line SPL1 and a second sub-pixel line SPL2, at least one transmissive portion TA of the first sub-pixel line SPL1 and at least one transmissive portion TA of the second sub-pixel line SPL2 may be arranged to contact each other.

Further, at a boundary of the second subject line SPL2 and a third sub-pixel line SPL3, at least one light emitting portion EA of the second sub-pixel line SPL2 and at least one light emitting portion EA of the third sub-pixel line SPL3 may be arranged to contact each other.

At a boundary of the third subject line SPL3 and a fourth sub-pixel line SPL4, at least one transmissive portion TA of the third sub-pixel line SPL3 and at least one transmissive portion TA of the fourth sub-pixel line SPL4 may be arranged to contact each other.

Accordingly, as respective transmissive portions TA in adjacent sub-pixel lines SPL are arranged to contact each other, a width of a transmissive area formed by one or more transmissive portions TA located between light emitting portions EA may be increased.

That is, a slit structure may be formed by one or more transmissive portions TA located between light emitting portions EA, and in this case, a structure with a slit of a large width may be formed by increasing a width of one or more transmissive portions TA between the light emitting portions EA.

Since a width of a slit formed by one or more transmissive portions TA located in sub-pixels SP is increased, a diffraction phenomenon caused by light passing through the transmissive portion(s) TA may be reduced. Accordingly, even when an area of one or more transmissive portions TA located in sub-pixels SP is maintained, the diffraction phenomenon caused by the transmissive portion(s) TA may be reduced.

Like this, although the diffraction phenomenon may be reduced by adjusting a structure in which one or more transmissive portion(s) TA in sub-pixels SP are arranged, since the transmissive portion(s) TA still form a structure with a slit of an equal width, the diffraction phenomenon may be still present.

In accordance with embodiments of the present disclosure, a method is provided of preventing the diffraction phenomenon caused by light passing through one or more transmissive portion(s) TA by adjusting a location of a transmissive portion TA or a light emitting portion EA in a sub-pixel SP for causing a width of a slit formed by one or more transmissive portions TA to be irregular.

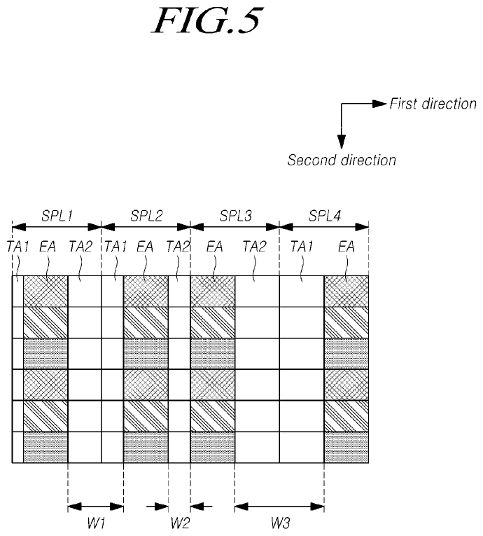

In another embodiment, FIG. 5 illustrates a structure in which one or more light emitting portions EA and one or more transmissive portions TA are located in a plurality of sub-pixel lines SPL.

Referring to FIG. 5, one or more transmissive portion(s) TA may be located on both sides of one or more light emitting portion(s) included in a first sub-pixel line SPL1.

In one example, one or more first transmissive portion(s) TA1 may be located on the left side of one or more light emitting portion(s), and one or more second transmissive portion(s) TA2 may be located on the right side of the one or more light emitting portion(s). Here, a ratio between an area of the one or more first transmissive portion(s) TA1 and an area of the one or more second transmissive portion(s) TA2, which are located in the first sub-pixel line SPL1, may be X1:Y1. Further, a ratio between areas of transmissive portions TA may mean a ratio between widths.

One or more first transmissive portion(s) TA1 and one or more second transmissive portion(s) TA2 may be located on both sides of one or more light emitting portion(s) included in a second sub-pixel line SPL2, respectively. Further, a ratio between an area of the one or more first transmissive portion(s) TA1 and an area of the one or more second transmissive portion(s) TA2, which are located in the second sub-pixel line SPL2, may be X2:Y2.

A ratio between an area of one or more first transmissive portion(s) TA1 and an area of one or more second transmissive portion(s) TA2 located on both sides of one or more light emitting portion(s), respectively, which are included in a third sub-pixel line SPL3, may be X3:Y3. A ratio between an area of one or more first transmissive portion(s) TA1 and an area of one or more second transmissive portion(s) TA2 located on both sides of one or more light emitting portion(s), respectively, which are included in a fourth sub-pixel line SPL4, may be X4:Y4.

Here, when an area of a transmissive portion TA included in each sub-pixel SP has a value of 100, each of X1, X2, X3, X4, Y1, Y2, Y3, and Y4 may have a value of 0 or more and 100 or less. That is, in some instances, a transmissive portion TA in a sub-pixel SP may be located only on one side of a light emitting portion EA.

Further, a sum of areas of transmissive portions included in respective sub-pixels SP may be constant. That is, each of X1+Y1, X2+Y2, X3+Y3, and X4+Y4 has a value of 100, and an area of one or more transmissive portions in each sub-pixel SP may be constant.

In this situation, a width of a transmissive area formed by one or more transmissive portion(s) TA located between sub-pixel lines SPL may not be constant.

In one example, one or more second transmissive portion(s) TA2 of the first sub-pixel line SPL1 and one or more first transmissive portion(s) TA1 of the second sub-pixel line SPL2 may be combined to form a transmissive area between the first subject line SPL1 and the second sub-pixel line SPL2. Further, a width W1 of the transmissive area may be Y1+X2.

A width W2 of a transmissive area formed between the second sub-pixel line SPL2 and the third sub-pixel line SPL3 may be Y2+X3. Here, X3 is 0.

A width W3 of a transmissive area formed between the third sub-pixel line SPL3 and the fourth sub-pixel line SPL4 may be Y3+X4. Here, X4 is 100, and Y4 is 0.

Accordingly, the W1, W2, and W3 of the transmissive areas formed between corresponding sub-pixel lines SPL may be Y1+X2, Y2+X3, and Y3+X4, respectively. Here, Y1+X2 and Y2+X3 may be different. Further, the Y2+X3 and the Y3+X4 may be different. That is, widths of transmissive areas located to be adjacent in the first direction may not be equal.

Further, a transmissive area between the first sub-pixel line SPL1 and the second sub-pixel line SPL2 and a transmissive area between the third sub-pixel line SPL3 and the fourth sub-pixel line SPL4 may be formed such that Y1+X2 and Y3+X4 are different.

As widths of transmissive areas located to be adjacent are designed to be different from each other, or widths of transmissive areas located both sides of one transmissive area are designed to be different from each other, it is possible to prevent transmissive areas located along the first direction from forming a structure of a slit with an equal size. Accordingly, it is possible to prevent the diffraction phenomenon caused by a transmissive area with a slit structure and improve the sharpness of images.

Further, by designing an area of a transmissive portion TA in each sub-pixel SP to be constant and widths of transmissive portions TA located to be adjacent in the second direction to be constant, it is possible to form easily a structure of a sub-pixel SP with a reduced diffraction phenomenon, while maintaining transmittance.

In each sub-pixel line SPL, a location of at least one light emitting portion EA or widths of transmissive portions TA located on both sides of the light emitting portion EA may be determined such that a width of a transmissive area between light emitting portions EA cannot be constant. In another example, a sub-pixel line SPL may be randomly selected and disposed, from candidates in which a location of a light emitting portion EA or a width of one or more transmissive portion(s) TA is set to be different from another.

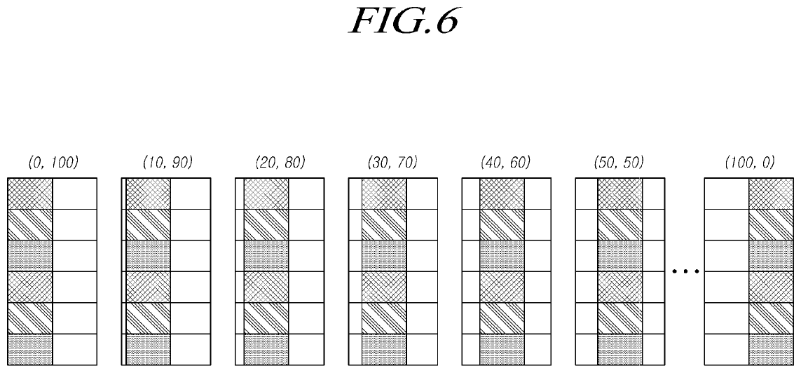

FIG. 6 illustrates examples of candidates in which one or more light emitting portions EA and one or more transmissive portions TA are located in each sub-pixel line SPL.

Referring to FIG. 6, when an entire area or width of one or more transmissive portions TA disposed in a sub-pixel line SPL has a value of 100, a width of one or more transmissive portions TA located on both sides of one or more light emitting portion(s) EA may be set, for example, on a per 10 basis. In some instances, the width may be set on a per 5 basis or on a per 1 basis; however, embodiments of the present disclosure are not limited thereto a specific value.

When the width of a transmissive portion TA is set on a per 10 basis, and a ratio between areas (or widths or other parameters) of transmissive portions TA located on both sides of a light emitting portion EA is represented as (X, Y), a total of 11 candidates, such as, (0, 100), (10, 90), (20, 80), (30, 70), (40, 60), (50, 50), (60, 40), (70, 30), (80, 20), (90, 10), and (100, 0), may be present as a structure of a sub-pixel line SPL.

Further, any sub-pixel line SPL randomly selected from the 11 candidates can be disposed; therefore, it is possible to prevent a slit with an equal width from being formed by one or more transmissive portion(s) TA included in the sub-pixel line SPL.

Here, even when the sub-pixel line SPL is randomly disposed, there may occur an instance where a width of one or more transmissive areas formed by combination of sub-pixel lines SPL is equal. In one example, when ratios between transmissive portions TA located on both sides of respective light emitting portions EA in three consecutive sub-pixel lines SPL is (70, 30), (60, 40), and (50, 50), widths of transmissive portions TA between corresponding sub-pixel lines SPL may be equally 90.

Accordingly, the forming of a slit with an equal width may be prevented by allowing a sub-pixel line SPL randomly selected from the preset candidates of sub-pixel lines SPL to be disposed, or a sub-pixel line SPL selected from candidates formed by combination of two sub-pixel lines SPL may be disposed.

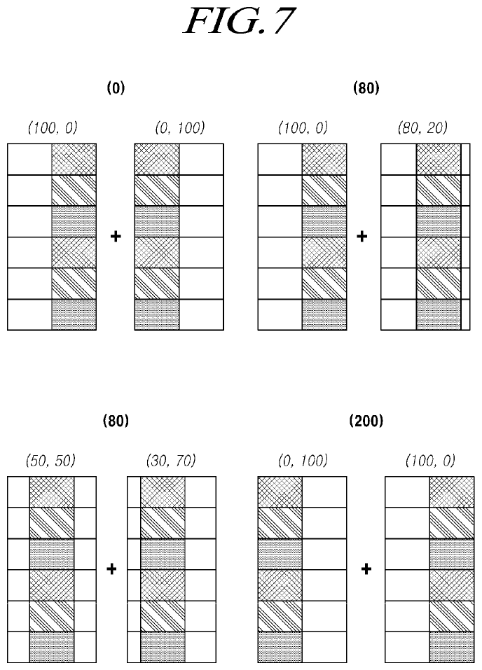

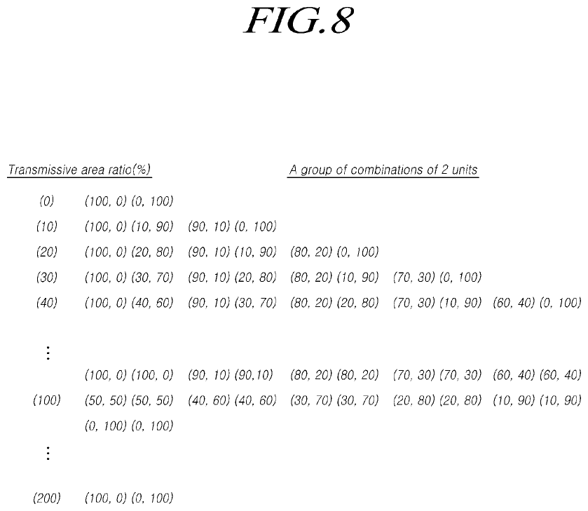

FIGS. 7 and 8 illustrate several structures in which one or more light emitting portions EA and one or more transmissive portions TA are variously arranged in sub-pixel lines SPL disposed to be adjacent.

Referring to FIG. 7, when sub-pixel lines SPL are disposed such that ratios, (X, Y), of areas of one or more transmissive portions TA located on both sides of one or more light emitting portions EA in sub-pixel lines SPL can be (100, 0) and (0, 100), respectively, a width of a transmissive area between the sub-pixel lines SPL may be 0.

Further, a width of a transmissive area between sub-pixel lines SPL may be 80 in a combination of a corresponding sub-pixel line with (X, Y) of (100, 0) and a corresponding sub-pixel line with (X, Y) of (80, 20) or a combination of a corresponding sub-pixel line with (X, Y) of (50, 50) and a corresponding sub-pixel line with (X, Y) of (30, 70). That is, these compositions may belong to an equal group (or a group of combinations).

In a combination of a sub-pixel line with (X, Y) of (0, 100) and a sub-pixel line with (X, Y) of (100, 0), a width of a transmissive area between the sub-pixel lines SPL may be 200.

Like this, according to each combination, a width of a transmissive area between sub-pixel lines SPL may be classified. Further, when these combinations are disposed to be adjacent, by configuring a width of a transmissive area formed between combinations to be different from a width of a transmissive area formed in each combination, widths of three consecutive transmissive areas may be configured to be different.

In one example, when each sub-pixel line SPL is regarded as one unit and one combination is formed of two units, a ratio in transmissive areas formed by each combination may be classified as shown in FIG. 8. Here, a transmissive area formed by a combination may mean a ratio of a transmissive area formed between sub-pixel lines SPL included in a combination.

Since an area of one or more transmissive portions TA located on one side of one or more light emitting portions EA in a sub-pixel line SPL is 0 or more and 100 or less, a ratio of a transmissive area formed between sub-pixel lines SPL in each combination may be formed on a per 10 unit in a range of 0 or more and 200 or less.

Accordingly, combinations of sub-pixel lines SPL being disposed to be adjacent may be determined taking account of a ratio between transmissive areas formed by respective combinations

In one example, a combination may be formed of one sub-pixel line selected from a combination with a transmissive area ratio of 30 and one sub-pixel line selected from a combination with a transmissive area ratio of 100 so that ratios of transmissive areas formed by adjacent combinations can be different. Further, when the selected combinations are disposed to be adjacent, a ratio of the transmissive areas between combinations may be different from 30 or 100.

That is, when a first corresponding combination is formed of (100, 0) and (30, 70), and a second corresponding combination is formed of (30, 70), (30. 70), a ratio of the transmissive areas between the combinations becomes 100 and a ratio of a transmissive area formed by the second combination becomes 100; therefore, the transmissive areas with the equal width are consecutively formed.

Accordingly, in case the second combination is formed of (80, 20) and (80, 20), it is possible to prevent a slit with an equal width from being formed by configuring consecutive transmissive area ratios to have 30(0+30), 150(70+80), and 100(20+80), respectively.

Like this, embodiments of the present disclosure, by allowing a width of a transmissive area formed in a specific direction by adjacent sub-pixel lines SPL to be formed irregularly, it is possible to prevent the diffraction phenomenon caused by the transparent area while maintaining a transmittance of a sub-pixel SP.

Further, embodiments of the present disclosure, by adjusting a shape or a location of a transmissive portion TA located in a sub-pixel SP, or by adjusting a structure in which one or more signal lines SL several types of signals to a sub-pixel SP are arranged, it is possible to prevent a slit from being formed periodically and reduce the diffraction phenomenon.

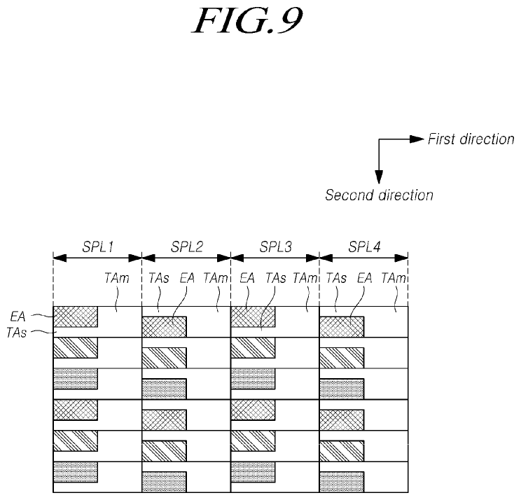

In another embodiment, FIG. 9 illustrates a structure in which one or more light emitting portions EA and one or more transmissive portions TA are located in a plurality of sub-pixel lines SPL in accordance with another embodiment of the present disclosure.

Referring to FIG. 9, a structure in which one or more light emitting portions EA and one or more transmissive portions TA are located in a sub-pixel line SP may be equal to a structure of a sub-pixel SP illustrated in FIG. 3C.

In each sub-pixel SP, a light emitting portion EA may be disposed, and a main transmissive portion TAm may be located on one side of the light emitting portion EA. Further, an auxiliary transmissive portion TAs connected to the main transmissive portion TAm may be located on the other side of the light emitting portion EA.

In a structure in which the main transmissive portion TAm disposed and connected along a second direction in a sub-pixel line SPL forms a slit, since the auxiliary transmissive portion TAs disposed along the first direction is connected to the main transmissive portion TAm, the slit structure formed by the main transmissive portion TAm may be removed.

Further, an auxiliary transmissive portion TAs disposed in an adjacent sub-pixel line SPL may be disposed asymmetrically.

That is, as shown in FIG. 9, one or more auxiliary transmissive portion(s) TAs disposed in a first sub-pixel line SPL1 and one or more auxiliary transmissive portion(s) TAs disposed in a second sub-pixel line SPL2 may be asymmetrical. Further, one or more auxiliary transmissive portion(s) TAs disposed in the second sub-pixel line SPL2 and one or more auxiliary transmissive portion(s) TAs disposed in a third sub-pixel line SPL3 may be asymmetrical.

Since the auxiliary transmissive portions TAs are disposed asymmetrically in adjacent sub-pixel lines SPL, it is possible to prevent a slit with a constant pattern from being formed through a connection of transmissive portions TAs included in the sub-pixel lines SPL.

Like this, a structure including a main transmissive portion TAm and an auxiliary transmissive portion TAs, in which a transmissive portion TA surrounds a light emitting portion EA, it is possible to reduce the diffraction phenomenon caused by a transmissive area by adjusting a location of the auxiliary transmissive portion TAs.

Further, as in the above example, the prevention of the diffraction phenomenon using the auxiliary transmissive portion TAs may be applied to a structure in which a ratio of an transmissive area formed by one or more transmissive portion(s) TA located on both sides of a light emitting portion EA is irregularly arranged.

Further, according to the embodiments of the present disclosure, it is possible to reduce the diffraction phenomenon through a structure in which a signal line SL for supplying a signal to a sub-pixel SP is arranged.

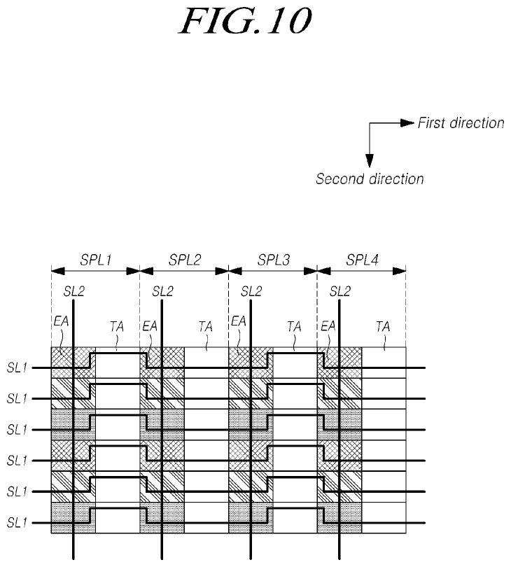

FIG. 10 illustrates an example of a structure in which a signal line is arranged in a plurality of sub-pixel lines SPL including one or more light emitting portions EA and one or more transmissive portions TA.

Referring to FIG. 10, signal lines for providing signals to respective sub-pixels SP may be arranged. For example, a plurality of first signal lines SL1 may be arranged along a first direction, and a plurality of second signal lines SL2 may be arranged along a second direction.

Here, the signal lines SL may be gate lines GL or data lines DL, or lines providing other signals or voltages for driving sub-pixels SP.

In a structure in which transmissive portions TA in sub-pixels SP are disposed to be connected along the second direction, the second signal lines arranged along the second direction may overlap light emitting portions EA. That is, an area of one of more transmissive portions TA can be prevented from being reduced due to arrangements of the second signal lines SL2.

At least a part of one or more first signal lines SL1 arranged along the first direction may be arranged to pass through one or more transmissive portions TA.

Here, the at least one first signal line SL1 disposed to pass through one or more transmissive portions TA may be asymmetrically arranged in an adjacent sub-pixel line SPL.

In one example, a first signal line SL1 may be arranged in a zigzag pattern in one or more transmissive portions TA of one or more adjacent sub-pixel line(s) SPL. That is, the first signal line SL1 may be located on an upper portion of corresponding transmissive portions TA in a first sub-pixel line SPL1 and be located on a lower portion of transmissive portions TA in a second sub-pixel line SPL2.

Since an area in which the first signal line SL1 is arranged may not be a transparent area, occurrences of the diffraction phenomenon caused by an regular arrangement of transmissive portions TA may be reduced by configuring the first signal line SL1 to be arranged asymmetrically in the transmissive portions TA disposed to be adjacent.

Further, since the first signal line SL1 is located on a straight line in one or more areas overlapping one or more light emitting portion(s) EA, only regular pattern forming of transmissive portions TA can be prevented without affecting a structure for a connection with a circuit component disposed in the one or more light emitting portion(s) EA.

Such a signal line arrangement may be applied, as in the example described above, to a structure in which widths of transmissive portions TA formed by adjacent sub-pixel lines SPL are irregularly formed or a structure in which locations or shapes of the transmissive portions TA are adjusted.

Further, according to embodiments of the present disclosure, in locating irregularly transmissive portion(s) TA of a sub-pixel line SPL, a ratio of the transmissive portion(s) TA may be determined taking account of a structure in which one or more signal lines are arranged outside of an active area AA in which sub-pixels SP are arranged.

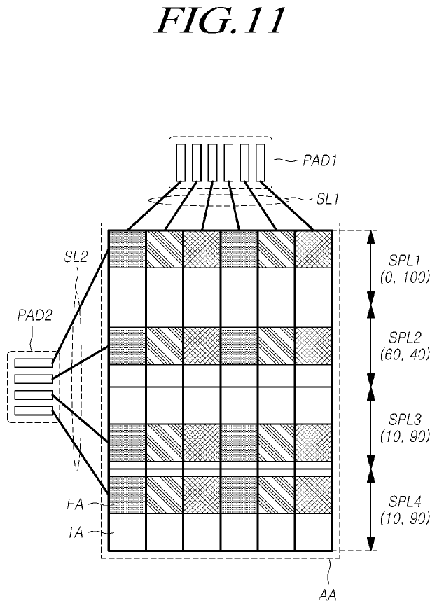

FIG. 11 illustrates a structure in which light emitting portions and transmissive portions TA are disposed in a plurality of sub-pixel lines taking account of at least one signal line located outside of the active area AA.

Referring to FIG. 11, widths of one or more transmissive portions TA disposed respective sub-pixel lines SPL of a plurality of adjacent sub-pixel lines SPL may be different.

Further, a signal line SL providing a signal to each sub-pixel line SPL may be arranged.

Such a signal line SL may be electrically connected to one or more light emitting portions EA including one or more light emitting elements ED, such as a light emitting diodes, and circuit components in a sub-pixel line SPL, and may be electrically connected to a conductive pad including a plurality of pads for a connection with a driving circuit outside of the active area AA.

In one example, a plurality of first signal lines SL1 may be connected to a first conductive pad PAD1 and a plurality of second signal lines SL2 may be connected to a second conductive pad PAD2.

Here, an interval between signal lines SL may be smaller as the conductive pad is closer. Accordingly, as an interval between light emitting portions EA in a sub-pixel line SPL is small, an interval between signal lines SL connected to the conductive pad may be smaller.

In this situation, since signal lines SL may not be easily arranged in an area in which the conductive pad is located, for preventing a slit from being formed, while a ratio of a transmissive area between sub-pixel lines SPL is configured to be irregular, a ratio of a transmissive area between light emitting portions EA may be maintained to a certain level or more.

In one example, a ratio of a transmissive area formed between light emitting portions EA included two sub-pixel lines SPL may be configured to be 20 or more. In another example, by configuring a ratio of the transmissive area to be 0 or more, it is possible to configure a structure in which light emitting portions EA contact one another not to be formed.

Like this, it is possible to arrange easily signal lines SL, by enabling a ratio of a transmissive area to be irregular to prevent the diffraction phenomenon and allowing the ratio of the transmissive area to be included in a certain range.

Further, according to embodiments of the present disclosure, since locations of one or more light emitting portions EA and one or more transmissive portions TA may be adjusted for each sub-pixel line SPL, it is possible to configure one or more transmissive portions TA included in a sub-pixel SP not to be located on an outermost edge in a boundary of the active area AA.

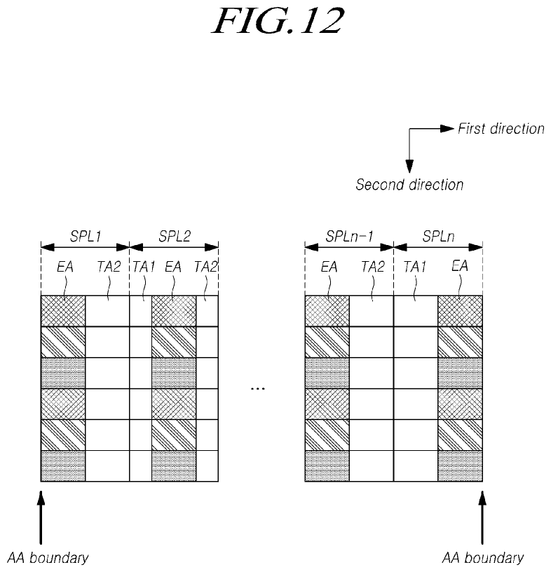

FIG. 12 illustrates a structure in which at least one light emitting portion and at least one transmissive portion TA are located in a boundary of the active area.

Referring to FIG. 12, when N number of sub-pixel lines is arranged in the active area AA, by configuring a ratio of a transmissive area between adjacent sub-pixel lines SPL to be formed irregularly, it is possible to prevent the diffraction phenomenon caused by the forming of a slit with an equal width.

At this time, in a boundary of the active area AA, a transmissive portion TA may be configured not to be located between a light emitting portion EA and the boundary of the active area AA.

In one example, a transmissive portion TA may not be located between a light emitting portion EA and a boundary of the active area AA in a first sub-pixel line SPL1. Further, a transmissive portion TA may not be located between a light emitting portion EA and a boundary of the active area AA in an nth sub-pixel line SPLn.

In a structure in which a sub-pixel SP includes a transmissive portion TA, there is a possibility that a light emitting portion EA of a sub-pixel SP located in an outermost area may be recognized as the active area AA. Accordingly, when the transmissive portion TA is located to contact a boundary of the active area AA, there is a possibility that the active area AA may be recognized as being reduced.

According to the embodiments of the present disclosure, in adjusting a location of one or more light emitting portions EA for adjusting a width of a one or more transmissive portions TA, in a boundary of the active area AA, by configuring the one or more light emitting portions EA to contact the boundary of the active area AA, it is possible to prevent the active area AA from being recognized as being reduced in a structure in which a sub-pixel SP includes a transmissive portion TA.

In accordance with the embodiments of the present disclosure, in a structure in which a transmissive portion TA is included in a sub-pixel SP, by configuring a ratio of a transmissive area formed by transmissive portions TA of adjacent sub-pixels SP between adjacent sub-pixel lines SPL to be formed irregularly through a location adjustment of a light emitting portion, it is possible to prevent a slit with an equal width from being formed.

Accordingly, by constantly maintaining an area of one or more transmissive portions TA in each sub-pixel SP, the diffraction phenomenon caused by light passing through a transmissive area between sub-pixel lines SPL can be prevented without reducing transmittance formed by the sub-pixel SP; thus, the sharpness of images in a transparent display device can be improved.

The above description has been presented to enable any person skilled in the art to make and use the technical idea of the present disclosure, and has been provided in the context of a particular application and its requirements. Various modifications, additions and substitutions to the described embodiments will be readily apparent to those skilled in the art, and the general principles defined herein may be applied to other embodiments and applications without departing from the spirit and scope of the present disclosure. The above description and the accompanying drawings provide an example of the technical idea of the present disclosure for illustrative purposes only. That is, the disclosed embodiments are intended to illustrate the scope of the technical idea of the present disclosure. Thus, the scope of the present disclosure is not limited to the embodiments shown, but is to be accorded the widest scope consistent with the technical idea presented in the disclosure.

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

What is claimed is:

1. A display device, comprising:
a plurality of first signal lines arranged in a first direction;
a plurality of second signal lines arranged in a second direction different from the first direction; and
a plurality of sub-pixels each receiving signals from at least one of the first signal lines and at least one of the second signal lines, each of the plurality of sub-pixels including a light emitting portion and at least one transmissive portion located adjacent to at least one side of the light emitting portion,
wherein the plurality of sub-pixels includes three sub-pixels being adjacently arranged in the first direction, and
wherein, when a ratio between areas of transmissive portions located on both sides of a light emitting portion of a first sub-pixel of the three sub-pixels is X1:Y1, a ratio between areas of transmissive portions located on both sides of a light emitting portion of a second sub-pixel of the three sub-pixels is X2:Y2, and a ratio between areas of transmissive portions located on both sides of a light emitting portion of a third sub-pixel of the three sub-pixels is X3:Y3,
wherein each sum X1+Y1, X2+Y2 and X3+Y3 are equal to each other, and a sum of Y1+X2 and a sum of Y2+X3 are different from each other.

2. The display device according to claim 1, wherein the X1 is different from at least one of the X2 and the X3.

3. The display device according to claim 1, wherein the X1, the X2 and the X3 are different from one another.

4. The display device according to claim 1, wherein when each of the sum of X1+Y1, the X2+Y2 and the X3+Y3 is 100, each of the X1, the X2, the X3, the Y1, the Y2 and the Y3 is 0 or more and 100 or less.

5. The display device according to claim 1, wherein a ratio between areas of transmissive portions located on both sides of light emitting portions disposed in adjacent sub-pixels in the second direction is constant.

6. The display device according to claim 1, wherein the plurality of sub-pixels each further includes an auxiliary transmissive portion located in an additional side of the light emitting portion in addition to both sides of the light emitting portion.

7. The display device according to claim 6, wherein auxiliary transmissive portions of adjacent sub-pixels of the plurality of sub-pixels are disposed asymmetrically.

8. The display device according to claim 1, wherein the at least one of the second signal lines is disposed to overlap with the light emitting portion, and at least a part of the at least one of the first signal lines is disposed to overlap with an area other than the light emitting portion.

9. The display device according to claim 8, wherein the at least a part of the at least one of the first signal lines disposed to overlap with the area other than the light emitting portion is arranged asymmetrically in adjacent sub-pixels.

10. The display device according to claim 1, wherein the light emitting portion is an area in which a light emitting element and at least one circuit component of each of the plurality of sub-pixels are disposed, and the at least one transmissive portion is an area other than the light emitting portion of each of the plurality of sub-pixels.

11. A display device, comprising:
a plurality of sub-pixels arranged in an active area;
a plurality of light emitting portions included in the respective plurality of sub-pixels; and
a plurality of transmissive portions included in the respective plurality of sub-pixels, and located on at least one side of the respective plurality of light emitting portions,
wherein a width of each of the plurality of transmissive portions adjacently disposed in a first direction is different, and a width of each of the plurality of transmissive portions adjacently disposed in a second direction different from the first direction are constant.

12. The display device according to claim 11, wherein in the plurality of transmissive portions disposed in the first direction, widths of two transmissive portions located on both sides of any one transmissive portion are different from each other.

13. The display device according to claim 11, wherein in an area except for at least one sub-pixel of the plurality of sub-pixels contacting a boundary of the active area, a width of at least one transmissive portion of the plurality of transmissive portions located between at least two light emitting portions of the plurality of light emitting portions is greater than 0.

14. The display device according to claim 11, wherein at least one transmissive portion of the plurality of transmissive portions included in at least one sub-pixel of the plurality of sub-pixels contacting a boundary of the active area is located in an area except for an area between the boundary of the active area and at least one of the plurality of light emitting portions.

15. A display device, comprising:
a plurality of first signal lines arranged in a first direction;
a plurality of second signal lines arranged in a second direction different from the first direction; and
a plurality of sub-pixels each receiving signals from at least one of the first signal lines and at least one of the second signal lines, each of the plurality of sub-pixels including a light emitting portion and a transmissive portion located on one side of the light emitting portion,
wherein in a boundary of two sub-pixels adjacently disposed in the first direction among the plurality of sub-pixels, light emitting portions included in the two sub-pixels are disposed to contact each other or transmissive portions included in the two sub-pixels are disposed to contact each other.

16. The display device according to claim 15, wherein the plurality of sub-pixels each further include an auxiliary transmissive portion located on another side different from the one side of the light emitting portion and connected to the transmissive portion.

17. The display device according to claim 16, wherein auxiliary transmissive portions in adjacent sub-pixels of the plurality of sub-pixels are disposed asymmetrically.

18. The display device according to claim 15, wherein the at least one of the second signal lines is disposed to overlap with the light emitting portion, and at least a part of the at least one of the first signal lines is disposed to overlap with an area other than the light emitting portion.

19. The display device according to claim 18, wherein the at least a part of the at least one of the first signal lines disposed to overlap with the area other than the light emitting portion is arranged asymmetrically in adjacent sub-pixels of the plurality of sub-pixels.

20. The display device according to claim 15, wherein a transmissive portion included in at least one sub-pixel located in an outermost area among the plurality of sub-pixels is located in an area between an outer boundary of the outermost area and a light emitting portion of the at least one sub-pixel.
